(19) United States
(12) Patent Application Publication
(10) Pub. No.: US 2011/0017267 A1
(43) Pub. Date: Jan. 27, 2011

(54) RECEIVER FOR CONCENTRATING PHOTOVOLTAIC-THERMAL SYSTEM

(76) Inventors: Joseph Isaac Lichy, San Jose, CA (US); Brian Edward Atchley, Oakland, CA (US); Ratson Morad, Palo Alto, CA (US); Gilad Almogy, Palo Alto, CA (US); Adam Brian Reich, Berkeley, CA (US); John Lawler, San Francisco, CA (US); Nathan Phillips Beckett, Oakland, CA (US)

Correspondence Address: K&L Gates LLP;IP Docketing, 630 HANSEN WAY, PALO ALTO, CA, 94304, US

(21) Appl. No.: 12/622,416

(22) Filed: Nov. 19, 2009

(51) Int. Cl. H01L 31/052; H01L 31/048; H01L 31/042

(52) U.S. Cl. 136/246; 136/251; 136/244

(57) ABSTRACT

Systems, methods, and apparatus by which solar energy may be collected to provide electricity or a combination of heat and electricity are disclosed herein. Examples of solar energy receivers are disclosed that may be used to collect concentrated solar radiation.

### FIELD OF THE INVENTION

The invention relates generally to the collection of solar energy to provide electric power or electric power and heat.

### BACKGROUND

Alternate sources of energy are needed to satisfy ever increasing world-wide energy demands. Solar energy resources are sufficient in many geographical regions to satisfy such demands, in part, by provision of electric power and useful heat.

### SUMMARY

Systems, methods, and apparatus by which solar energy may be collected to provide electricity or a combination of heat and electricity are disclosed herein.

In one aspect, a solar energy receiver comprises a linearly extending substrate comprising two or more coolant channels extending through the substrate along its long axis, and solar cells in thermal contact with the substrate. The substrate is formed by an extrusion process from, for example, aluminum or an aluminum alloy. The coolant channels may have, for example, substantially rectangular cross sections perpendicular to the long axis of the substrate. The solar cells may be included, for example, in a stack of two or more laminated layers disposed on the substrate.

In another aspect, a solar energy receiver comprises a substrate having a front surface, a back surface opposite to the front surface, and side surfaces, and a plurality of solar cells disposed in a stack of laminated layers on the front surface of the substrate. The solar receiver also comprises one or more electrical components disposed on the back surface of the substrate, and an electrically insulated interconnect passing from the front surface of the substrate, around a side surface of the substrate, to the back surface of the substrate to electrically interconnect one or more of the solar cells to one or more of the electrical components. The solar energy receiver may further comprise a solar radiation shield positioned to protect the electrical components from illumination by solar radiation, and/or a solar radiation shield positioned to protect the electrically insulated interconnect from illumination by solar radiation.

In some variations of this aspect, the electrically insulated interconnect comprises a laminated structure including one or more electrical conductors laminated between two or more electrically insulating layers. In some such variations, at least an end portion of the laminated structure of the electrically insulated interconnect is included in the stack of laminated layers on the front surface of the substrate. The laminated structure of the electrically insulated interconnect may be protected by a shield from illumination by solar radiation.

In another aspect, a solar energy receiver comprises a linearly extending substrate comprising two or more coolant channels extending through the substrate along its long axis, solar cells in thermal contact with the substrate, and an end piece providing separate fluid flow paths to an end of each coolant channel and otherwise sealing an end of the substrate to coolant flow. The substrate may be sealed to coolant flow by, for example, a weld between the end piece and the substrate. The solar energy receiver may further comprise a coolant manifold that distributes coolant from an inlet of the manifold to the separate coolant flow paths in the end piece. A gasket may be located between the coolant manifold and the end piece to seal their interface. The gasket may comprise, for example, an orifice for each coolant channel in the substrate, with the orifices controlling coolant flow through corresponding coolant channels.

In another aspect, a solar energy receiver comprises a linearly extending substrate comprising two or more coolant channels extending through the substrate along its long axis, solar cells in thermal contact with the substrate, and an orifice for each coolant channel in the substrate, with each orifice providing a pressure drop during coolant flow greater than the pressure drop across its corresponding coolant channel. The orifices may be provided, for example, in a gasket otherwise sealing an end of the substrate to coolant flow.

In another aspect, a solar energy receiver comprises a substrate, a conversion coating on a surface of the substrate, and a plurality of solar cells disposed in a stack of laminated layers on the conversion coated surface of the substrate. The substrate may extend linearly and comprise two or more coolant channels extending through the substrate along its long axis. The substrate may be formed, for example, by an extrusion process.

In another aspect, a solar energy receiver comprises a linearly extending substrate having a front surface, a back surface, and side surfaces, with the side surfaces each comprising a slot running parallel to a long axis of the substrate along at least a portion of the substrate. The slots may have, for example, substantially t-shaped cross sections perpendicular to their long axes. The solar receiver further comprises solar cells disposed on the front surface of the substrate. The substrate may comprise two or more coolant channels extending through the substrate along its long axis. The substrate may be formed by an extrusion process.

In another aspect, a solar energy receiver comprises a plurality of solar cells electrically connected in series and a first plurality of bypass diodes. Each of the bypass diodes is connected between a conductor (i.e., the same conductor) and a different location in the series of solar cells. The solar energy receiver may further comprise a second plurality of bypass diodes electrically connected in series with each other and, separately, in parallel with different ones or groups of the solar cells. The solar receiver may further comprise a linearly extending substrate on which the solar cells are disposed, with the first plurality of bypass diodes electrically connected to bypass solar cells located at an end portion of the substrate. The substrate may comprise, for example, two or more coolant channels extending through the substrate along its long axis.

In another aspect, a solar energy receiver comprises a linearly extending substrate comprising two or more coolant channels extending through the substrate along its long axis, solar cells in thermal contact with the substrate, and a compression plug at least partially inserted into and sealing an end of one of the coolant channels. The compression plug may comprise, for example, a plug portion, a gasket on the plug portion, and a wedge portion that may be drawn against the plug portion to press the gasket against an interior wall of a coolant channel to thereby seal the coolant channel.

In another aspect, a solar energy receiver comprises a substrate having a front surface, a back surface opposite to the front surface, and side surfaces. A plurality of solar cells is disposed on the front surface of the substrate. The solar energy receiver also comprises an enclosure enclosing one or more electrical components electrically connected to one or more of the solar cells. A portion of the enclosure is shaped to define a slot dimensioned to fit around a portion of the front surface of the substrate, a side surface of the substrate, and a portion of the back surface of the substrate.

In another aspect, a solar energy receiver comprises a first linearly extending substrate having a substantially rectangular cross-section and comprising two or more coolant channels extending through the substrate along its long axis, a first plurality of solar cells disposed on a surface of the first substrate, a second linearly extending substrate having a substantially rectangular cross section and comprising two or more coolant channels extending through the substrate along its long axis, and a second plurality of solar cells disposed on a surface of the second substrate. The first substrate and the second substrate are mechanically coupled to each other to form a V-shape with a long axis of the first substrate parallel to a long axis of the second substrate and with the surfaces on which the solar cells are disposed facing outwards. The V-shape may make an interior angle of, for example, about 90 degrees.

The solar cells disposed on the first substrate may be electrically connected, for example, in series or in parallel with those on the second substrate. Coolant may flow, for example, in series or in parallel through the first and second substrates.

The solar energy receivers of the various aspects summarized above may provide, for example, an electrical output, a heat output (in the form of heated coolant, for example), or both an electrical and a heat output. The receivers may be illuminated by concentrated radiation, for example, in a trough, linear Fresnel, or any other suitable solar energy collection system.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIGS. 1A and 1B show, respectively, front and back views of an example solar energy receiver.

FIGS. 2A and 2B show cross sections of the example solar energy receiver of FIGS. 1A and 1B.

FIGS. 3A-3C show example wiring layouts on the front and back sides of a string of solar cells that may be used in solar energy receivers.

FIGS. 4A and 4B show example circuit diagrams for solar energy receivers.

FIGS. 5A and 5B show exploded views of layers of an example lamination stack disposed on a substrate in a solar energy receiver and layers of a laminate structure electrical interconnect.

FIGS. 6A-6C show a structure allowing electrical interconnection of solar cells on one face of a solar energy receiver with (e.g., a junction and/or diode box positioned on) an opposite face of the solar energy receiver.

FIGS. 7A and 7B show an example use of shields to protect a junction/diode box, and an electrical interconnection between the junction/diode box and solar cells on an opposite face of a solar energy receiver, from solar radiation concentrated on the receiver.

FIG. 8 shows an example junction/diode box comprising a slot dimensioned to fit around an edge of a solar energy receiver.

FIG. 9 shows an example use of a tape to seal an edge of a laminate disposed on a substrate in a solar energy receiver.

FIGS. 10A-10E show an example assembly that provides for flow of a coolant fluid into and through coolant channels in a substrate in a solar energy receiver.

FIG. 11 shows an example fluid interconnection between two solar energy receivers.

FIG. 12 shows another example assembly that provides for flow of a coolant fluid into and through coolant channels in a substrate in a solar energy receiver.

FIG. 13 shows another example assembly that provides for flow of a coolant fluid into and through coolant channels in a substrate in a solar energy receiver.

FIGS. 14A and 14B show an example plug that may be used to plug the ends of coolant fluid channels in a substrate in a solar energy receiver.

FIGS. 15A-15C show an example of a solar energy receiver assembly comprising two receivers arranged to form a V shape.

FIG. 16 shows an example trough solar energy collector.

FIG. 17 shows an example linear Fresnel solar energy collector.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries rather than to require that parallel rows of reflectors or solar cells, for example, or any other parallel arrangements described herein be exactly parallel.

This specification discloses apparatus, systems, and methods by which solar energy may be collected to provide electricity or a combination of electricity and heat. Examples of solar energy receivers are disclosed that may be used, for example, in trough or linear Fresnel solar energy collectors in which one or more mirrors concentrate solar radiation onto such a receiver. Solar (e.g., photovoltaic) cells in the receivers provide an electrical output. The solar cells may, in some variations, be actively cooled by a coolant that flows through the receiver. In some variations, heat collected by the coolant may also be made available for use as an energy source.

Receivers as disclosed herein may be used, for example, in some variations of the methods, apparatus, and systems disclosed in U.S. Provisional Patent Application Ser. No. 61/249,151, incorporated herein by reference in its entirety.

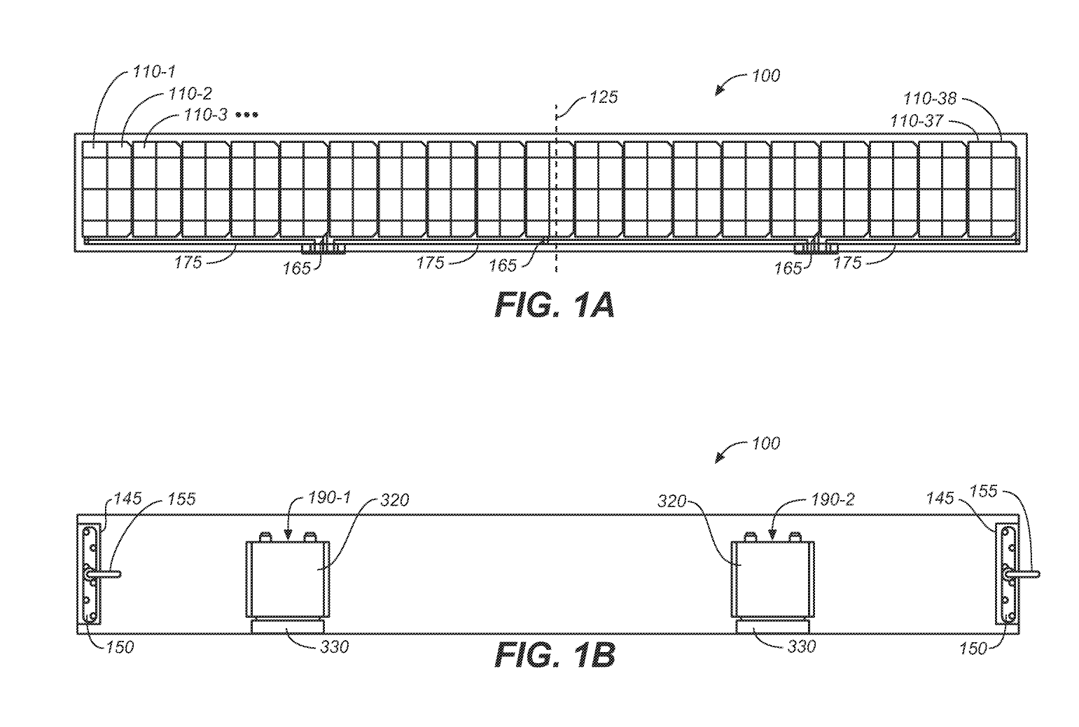

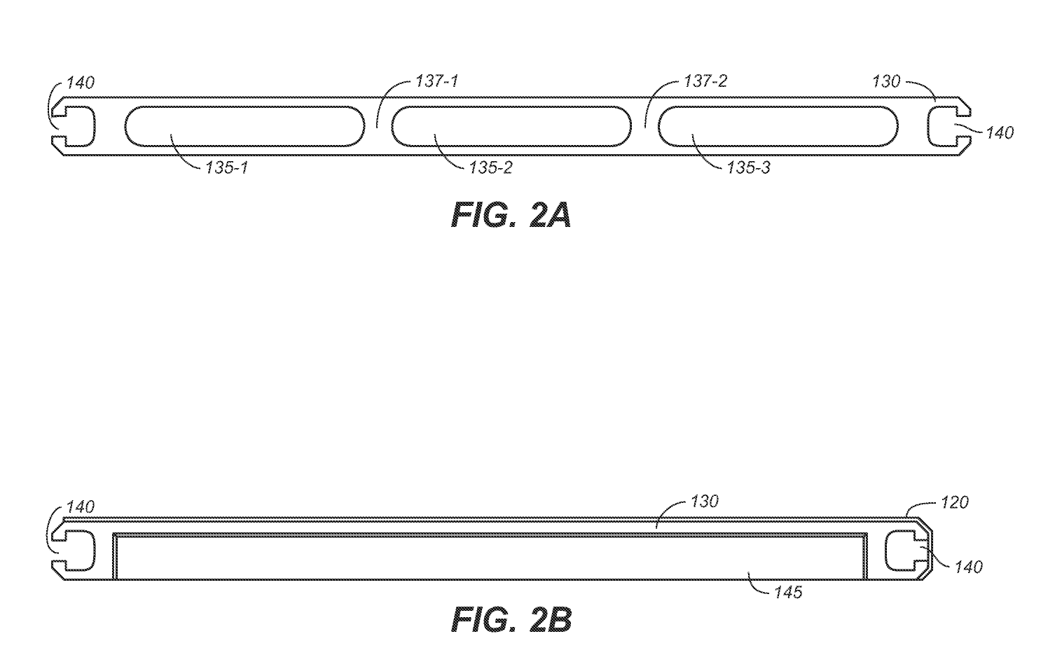

Referring now to FIGS. 1A, 1B, 2A, and 2B, a solar energy receiver 100 comprises a plurality of solar cells 110 disposed in a lamination stack 120 on a top surface of a substrate 130. Solar cells 110 may be, for example, DelSolar D6G(3B) solar cells available from DelSolar Co., Ltd. of Hsinchu Taiwan, R.O.C., but any suitable solar cells may be used. Suitable solar cells may include, for example, conventional single or multi-crystalline silicon solar cells, thin film (e.g., amorphous silicon, cadmium telluride, or copper indium gallium selenide) solar cells, and III-V solar cells. In one example, solar cells 110 are DelSolar D6G(3B) solar cells diced in quarters of substantially even width and/or substantially equal areas normal to their 3 millimeter (mm) bus bar pads. In one example, solar cells 110 have dimensions of about 156 mm by about 29 mm, and are arranged on substrate 130 with their long axes perpendicular to the long axis of the substrate.

Although FIG. 1A shows a single string of 38 solar cells 110-1-110-38 arranged in a single row, in other variations more or fewer solar cells may be used, and they may be arranged in one (as shown), two, or more parallel rows along the substrate. In addition, two or more receivers 100 may be positioned end-to-end and electrically and fluidly coupled to provide a larger receiver.

FIG. 2A shows a cross section of an example substrate 130, taken perpendicular to the long axis of receiver 100 and substrate 130 along line 125 shown in FIG. 1A. In the illustrated example, substrate 130 comprises three coolant fluid flow channels 135-1, 135-2, 135-3 running the length of substrate 130 parallel to its long axis, separated from each other by ribs 137-1 and 137-2. More or fewer coolant channels (and separating ribs) may be used in other variations. Coolant channels may have an approximately (e.g., substantially) rectangular cross section, as shown in FIG. 2A, or any other suitable cross section. Substrate 130 shown in FIGS. 2A and 2B further comprises t-slots 140 located in the sides of substrate 130 and running parallel to its long axis. T-slots 140 may run the full length of substrate 130 or, alternatively, along only one or more portions of each side. T-slots 140 may be used to mechanically couple receiver 100 to other components of a solar energy collector and may be, for example, configured to be compatible with nuts, bolts, other fasteners, or features on other mechanical elements that can be fit into the slots to mechanically couple receiver 100 to brackets, support structure, and/or other mechanical elements (see, e.g., below).

T-slots 140 in the sides of substrate 130 are not required, and may be placed elsewhere or absent in some variations of receiver 100. For example, one or more t-slots similar or identical to t-slots 140 may be located on the back surface of substrate 130, and may run, for example parallel to the long axis of substrate 130. Such t-slots may run the full length of substrate 130 or, alternatively, only along one or more portions of substrate 130. In some variations in which the sides of substrate 130 are not (or not much) utilized for mechanical connections, lamination stack 120 may wrap around one or more sides of substrate 130 (e.g., one or both sides running parallel to the long axis) to reach and adhere to portions of the back side of substrate 130. Such wrapping of lamination stack 120 may run substantially the full length of substrate 130 or, alternatively, only along one or more portions of 130. In the latter case, portions of the sides of substrate 130 may remain available to be relatively easily utilized for mechanical connections.

FIG. 2B shows another cross section of the example substrate 130 of FIG. 2A, perpendicular to its long axis, at or near an end of the substrate. In this example, an optional end cap 145 seals ends of coolant channels 135 (FIG. 2A). Referring now to FIG. 1B, which shows a back view of receiver 100, receiver 100 may further comprise optional coolant flow manifolds 150 attached to and fluidly coupled to end caps 145, and fluid interconnections 155 attached to manifolds 150. Coolant fluid flow paths, seals, and fluid interconnections between receivers 100 are discussed in greater detail below.

Substrate 130 (and hence receiver 100) may have, for example, a length of about 100 centimeters (cm) to about 400 cm, about 150 cm to about 350 cm, or about 275 cm to about 320 cm, a width of about 15 cm to about 25 cm, about 19 cm to about 22 cm, or about 20 cm to about 21 cm, and a thickness of about 1 cm to about 3 cm or about 1 cm to about 2 cm. In one example, substrate 130 has a length of about 160 centimeters (cm), a width of about 19.6 cm to about 20.8 cm, and a thickness of about 1.30 cm. In another example, substrate 130 has a length of about 275 cm, a width of about 19.6 cm to about 20.8 cm, and a thickness of about 1.30 cm. In another example, substrate 130 has length of about 320 cm, a width of about 19.6 cm to about 20.8 cm, and a thickness of about 1.30 cm.

In some variations, substrate 130 (comprising, e.g., t-slots and coolant fluid channels) is formed by an (e.g., conventional) extrusion process from, for example, aluminum or an aluminum alloy. Any other suitable material may also be used. In one example, substrate 130 is formed by an extrusion process from a 6063 aluminum alloy having a T-6 temper. One of ordinary skill in the art will recognize that extruded materials may be distinguished from cast materials, for example, by physical properties such as, for example, porosity, ductility, and and/or permeability.

Solar cells 110 may be electrically connected in any suitable manner described herein or known to one of ordinary skill in the art. In some variations, all of solar cells 110 are electrically connected in series. In other variations, some of solar cells 110, or some groups of solar cells 110, are electrically connected in parallel. Diodes may be used to bypass solar cells, or groups of solar cells, that would otherwise limit the electrical current due, for example, to a fault in the cell or cells or to shadowing (or any other cause of uneven illumination) of the cell or cells.

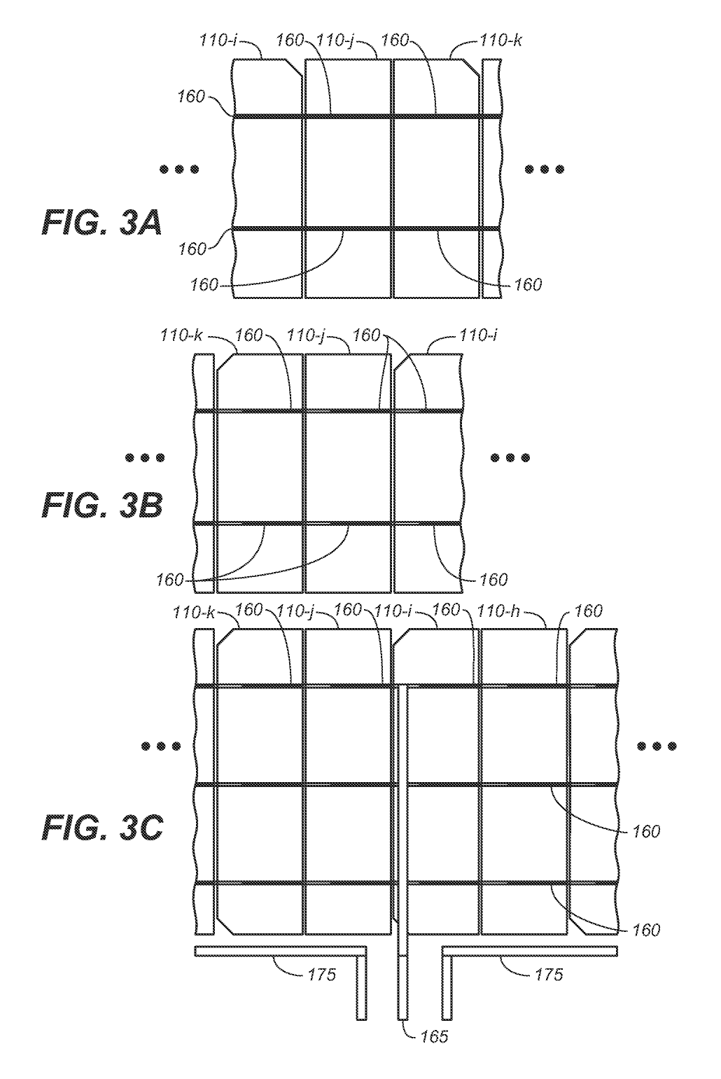

FIGS. 3A-3C show a portion of an example physical and wiring layout for solar cells 110. In the illustrated example, solar cells 110 (e.g., 110-h-110-k) are connected in series by electrical leads 160 (also referred to herein as tabs) that couple the front (illuminated side) of a cell to the back (unilluminated side) of an adjacent cell. For example, three tabs 160 electrically connect the front side of solar cell 110-i to the back side of solar cell 110-j. In the illustrated example, tabs 160 have a length selected to allow them to cross the entire width of the front sides of cells 110 but to cross only a portion (less than the entire width) of the back sides of the adjacent solar cells. This leaves an untabbed portion on the back of, and near the edge of, each of solar cells 110 that may be used to connect cells 110 to one or more bus bars (e.g., bus bar 165 in FIG. 3C) on the back side of solar cells 110. This also allows use of uniform tab lengths for tabs 160, the lengths of which might otherwise vary depending on the presence or absence of a bus bar beneath a particular cell. Solar cells 110 may be spaced apart from their neighbors by gaps of, for example, about 1 mm, about 1.5 mm, about 1.5 to about 2 mm, about 2 mm, about 3 mm, or more than about 3 mm.

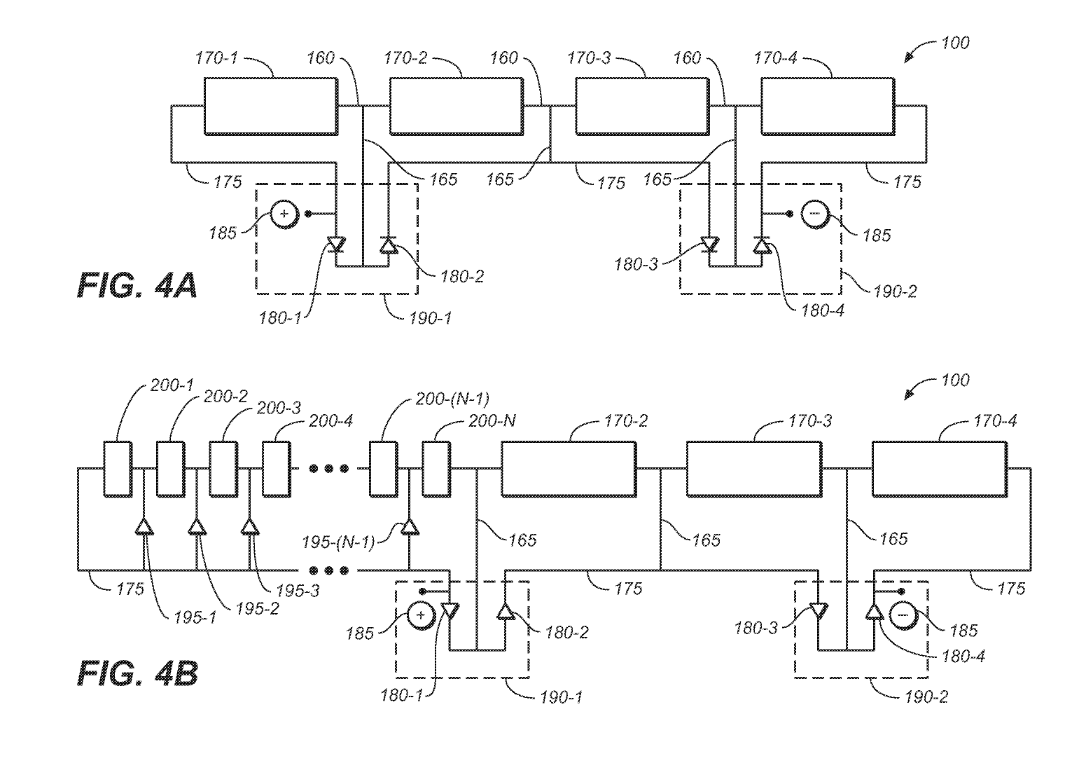

FIG. 4A shows an example circuit diagram for receiver 100. Groups 170-1-170-4 of solar cells 110 (not individually shown) are connected in series with each other, and also in parallel (via bus bars 175) with bypass diodes 180-1-180-4. Electrical sockets 185, providing an electrical output from receiver 100, may be used to interconnect one or more receivers 100 (in series or parallel) or to allow connection of receiver 100 to an electrical load. If one or more solar cells in a group (e.g., group 170-1) limits current through that group to below a threshold value, the corresponding bypass diode (e.g., bypass diode 180-1) will be forward biased and consequently turn on to allow current to bypass the underperforming group. In some variations, bypass diodes and electrical sockets are housed in junction/diode boxes (e.g., 190-1, 190-2) which may be located, for example, on a bottom (unilluminated) side of receiver 100 (see, e.g., FIG. 1B).

Referring again to FIG. 4A, groups 170 may include one or more solar cells, and may include equal or differing numbers of solar cells. Groups may include, for example, about 5 solar cells, about 10 solar cells, about 15 solar cells, or about 20 solar cells. Although in the example of FIG. 4A solar cells are grouped into four groups, each of which may be bypassed, any suitable number of bypassable groups, and any suitable number of cells per group, may also be used. Referring now to FIGS. 1A and 4A together, in the illustrated example group 170-1 includes solar cells 110-1-110-10, group 170-2 includes cells 110-11-110-19, group 170-3 includes cells 110-20-110-30, and group 170-4 includes cells 110-31-110-38.

FIG. 4B shows another example circuit diagram for receiver 100. This circuit is substantially similar to that of FIG. 4A, except that series connected solar cell groups 200-1-200-N have been substituted for solar cell group 170-1 of FIG. 4, and that additional bypass diodes 195-1-195-(N−1) have been placed each in parallel with a corresponding one of solar cell groups 200-1-200-(N−1). Bypass diodes 195 are electrically connected between a shared bus bar 175 and different ones of solar cell groups 200 and thus, unlike bypass diodes 180-1-180-4, are not in series with each other.

If one or more solar cells in one of groups 200 (e.g., group 200-3) limits current through that group to below a threshold value, the corresponding diode (e.g., diode 195-3) will turn on. Current will consequently bypass the limiting solar cell group (e.g., 200-3), as well as all other solar cell groups (e.g., 200-1 and 200-2) located earlier in the circuit. This arrangement provides the flexibility of allowing either a single (e.g. 200-1) or multiple solar cell groups to be bypassed with only a single diode voltage drop. In contrast, to bypass both of groups 170-2 and 170-3 requires two diode drops (across diodes 180-1 and 180-2). If, for example, during the course of a day (or a season) the edge of a shadow walks along receiver 100 from solar cell group 200-1 toward group 200-N, as these groups progressively join the shaded region of the receiver their corresponding diodes will turn on to bypass all shaded solar cell groups at the cost of a single diode drop.

Groups 200 may include one or more solar cells, and may include equal or differing numbers of solar cells. Groups 200 may include, for example, about 2 solar cells, about 5 solar cells, about 10 solar cells, about 15 solar cells, or about 20 solar cells. Any suitable number of groups 200 may be used. Diodes 195 may be, for example, incorporated into the solar cell circuit during manufacture of the solar cells, or be incorporated into or otherwise attached to substrate 130. Any suitable mounting of diodes 195, described herein or known to one of ordinary skill in the art, may be used.

In some variations, a receiver 100 is oriented such that, over time (e.g., during the course of a day or a year), solar radiation concentrated onto the receiver by reflectors, for example, walks along and off the length of receiver 100 and hence leaves a progressively lengthening portion of one end of receiver 100 unilluminated. This can occur, for example, as the angle of the sun above the horizon varies during the course of a day or a year. In such variations, the receiver 100 may include, at and/or near the end portion of the receiver experiencing the varying illumination, solar cell groups and diodes arranged as or similarly to groups 200 and diodes 195 in FIG. 4B.

Any suitable diodes may be used for diodes 180 and diodes 195. In some variations, diodes 180 and/or diodes 195 may be Vishay diodes having part number G1756 or Motorola diodes having part number MR756.

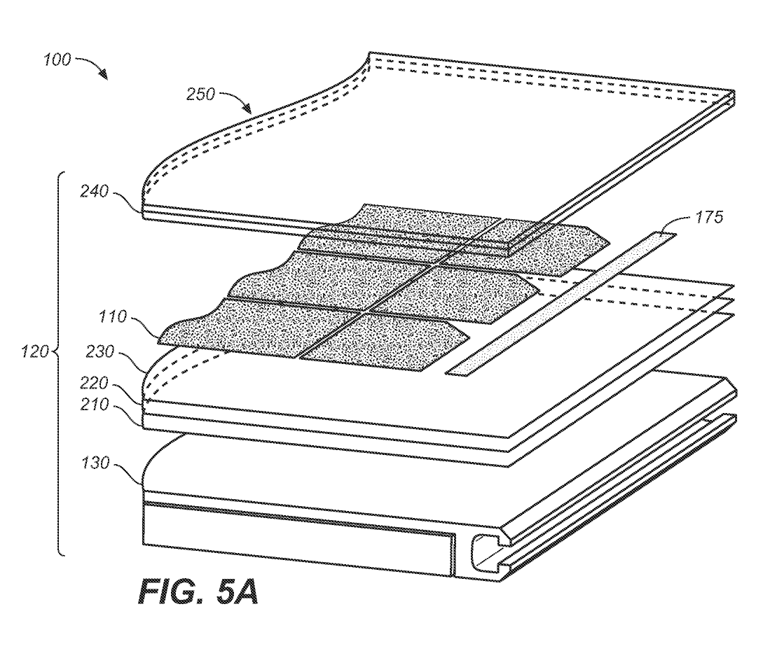

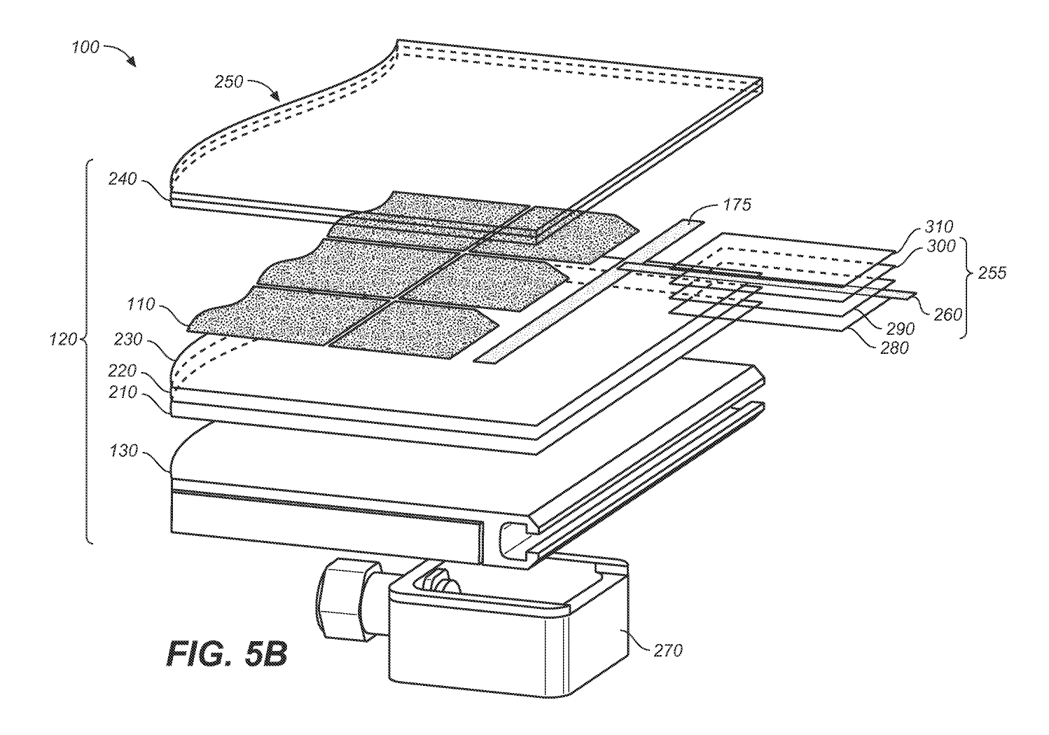

As noted earlier with respect to FIGS. 1A, 1B, 2A, and 2B, solar cells 110 are disposed in a lamination stack 120 on a top surface of substrate 130. Referring now to FIG. 5A, in one variation lamination stack 120 comprises an adhesive layer 210 disposed on substrate 130, an electrically insulating (i.e., dielectric) layer 220 disposed on adhesive layer 210, a second adhesive layer 230 disposed on electrically insulating layer 220, solar cells 110 (and associated electrical interconnects, such as bus bar 175 for example) disposed on second adhesive layer 230, third adhesive layer 240 disposed on solar cells 110, and transparent front sheet 250 disposed on third adhesive layer 240.

The adhesive layers adhere to adjacent surfaces to hold stack 120 together and to attach it to substrate 130. Electrically insulating layer 220 electrically isolates solar cells 110 from substrate 130. Front sheet 250 provides a flat surface and protects solar cells 110 from the ambient environment. The layers between substrate 130 and solar cells 110 also accommodate mismatches in thermal expansion between the solar cells and the substrate, and conduct heat from the solar cells to the substrate.

In some variations, the width (the dimension in the plane of substrate 130 perpendicular to the long axis of the substrate) of the solar cells is less than that of some or all other layers in stack 120. This provides gaps between the edges of the solar cells and the edges of stack 120 that deter migration of moisture from the ambient environment through the edges of stack 120 to the solar cells. In some variations, one or more such gaps have widths greater than about 5 mm, greater than about 8 mm, greater than about 12 mm, or greater than about 15 mm. In some variations, one or more such gaps have widths greater than or equal to about 12.7 mm. In some variations, the solar cells have widths approximately equal to that of the substrate, and other layers of stack 120 extend beyond an edge or edges of substrate 130 to accommodate a gap as described above. In some other variations, stack 120 has a width approximately equal to that of the substrate, and solar cells 110 have widths less than that of the substrate to accommodate a gap as described above.

In one variation, adhesive layer 210 has a thickness of about 200 microns (μm) to about 500 μm and is or includes an EVA (ethyl vinyl acetate) based adhesive such as, for example, 15420P/UF adhesive available from STR Inc.; electrically insulating layer 220 has a thickness of about 100 μm to about 150 μm and is or includes a PET (polyethylene terephthalate) such as, for example, Melinex 648 or Melinex 6430, available from Dupont Teijin Films; second adhesive layer 230 has a thickness of about 200 μm to about 500 μm and is or includes an EVA based adhesive such as, for example, 15420P/UF adhesive available from STR Inc; solar cells 110 have a thickness of about 180 μm to about 240 μm (e.g., 180±30 μm or 210±30 μm); third adhesive layer 240 has a thickness of about 200 μm to about 500 μm and is or includes an EVA based adhesive such as, for example, 15420P/UF adhesive available from STR Inc; and front sheet 250 has a thickness of about 50 μm to about 400 μm, or about 50 μm to about 125 μm, or about 100 μm to about 400 μm and is or includes an ETFE (ethylene-tetrafluoroethylene) fluoropolymer such as, for example, Tefzel® available from Dupont™.

In other variations stack 120 may include additional or fewer layers or may substitute different materials and/or thicknesses for one or more of the layers. For example, in some variations adhesive layer 210 and/or adhesive layer 230 may be or include a filled EVA adhesive. In some variations, insulating layer 220 is or includes a PET which is dyed, filled, or in some other manner colored white. In other variations, adhesive layer 210 is about 50 μm thick, and electrically insulating layer 220 is or includes a PFV (polyvinyl fluoride film) such as, for example, a Tedlar® PVF film available from Dupont™. In some variations front sheet 250 is or includes a PET (polyethylene terephthalate) such as, for example, Melinex 6430 available from Dupont Teijin Films, and has a thickness of about 50 μm to about 125 μm. In other variations, front sheet 250 is or includes a silicate (e.g., low iron) glass sheet, such as for example a sheet of Solar Diamant glass available from Saint Gobain Glass and having a thickness of about 2.5 mm to about 4 mm.

In some variations, solar cells 110 are surrounded by a suitable silicone gel, available for example from Dow Corning, that replaces layers 210, 220, 230, and 240, and front sheet 250 is or includes a low iron glass sheet. The silicone gel, or portions thereof, may be a filled silicone gel. The silicone gel may have a thickness, for example, of about 200 μm to about 1000 μm.

Tabbing and electrical interconnects (e.g., bus bar 175) associated with solar cells 110 may be formed, for example, from copper ribbon conventionally tinned with solder.

Filled EVA, PET, and silicone materials suitable for use in stack 120 may include materials filled, for example, with particles of MgO, Al₂O₃, ZnO, BN, and/or carbon, or a mixture of particles of any thereof.

In some variations, surfaces of substrate 130 to which stack 120 is to be attached are treated with a (e.g., chemical) conversion coating process to provide a conversion coating on substrate 130 to which a bottom layer of stack 120 will more strongly adhere and/or to improve corrosion resistance of substrate 130. Suitable conversion coating processes include, but are not limited to, conventional chromate, phosphate, and oxide conversion coating processes. In one variation, conversion coating is performed according to Mil Spec MIL-C-5541 class 1a. In other variations, surfaces of substrate 130 to which stack 120 is to be attached may be sand or bead blasted to promote adhesion.

In variations in which front sheet 250 is or includes an ETFE (ethylene-tetrafluoroethylene) fluoropolymer such as, for example, Tefzel®, the surface of front sheet 250 to be bonded to adhesive layer 240 may be pre-treated with a conventional corona etching process to promote adhesion.

Stack 120 may be formed, for example, by stacking the layers on substrate 130 in the order as described above and then heating them in a conventional thermal laminator apparatus. Other methods of forming stack 120 may also be used.

In some variations, the surface of substrate 130 to which solar cells 110 are attached is curved in the directions perpendicular to the long axis of receiver 100 so that the centerline of that surface running parallel to the long axis is higher than the outer portions of that surface. The surface may have a radius of curvature of, for example, about 5 meters to about 100 meters. In such variations, stack 120 (including solar cells 110) laminated to such a curved surface adopts a comparable curvature, which may reduce strain in solar cells 110 resulting from thermal expansion. Also, in some variations some or all of solar cells 110 are scored or scribed (e.g., using for example, laser scribing or mechanical scoring or scribing) on their unilluminated surface to guide cracking that might occur in solar cells 110 along directions that preserve electrical connections to cracked portions of the cells. For example, a solar cell may be scribed or scored in the direction parallel to the long axis of receiver 100, with a single scribed or scored line located between each pair of parallel tabs along the cell. Other suitable arrangements of scribing or scoring may also be used. Lasers suitable for scribing solar cells in this manner may include, for example, pulsed lasers lasing at 1064 nanometers. Suitable lasers may be available, for example, from ROFIN or from Epilog Laser.

In some variations, one or more wiring channels run within substrate 130 substantially parallel its long axis for the length of, or portions of the length of, receiver 100. The wiring channels comprise wires or other conductors electrically coupled to solar cells 110 by, for example, additional wires or conductors electrically connected to the solar cells (e.g., to bus bars in lamination stack 120 electrically connected to the solar cells) via holes passing from the wiring channel or channels through substrate 130 to the surface on which lamination stack 120 is disposed. In some variations, this arrangement allows electrical interconnection of two or more receivers through their ends via the wiring channel or channels. In some variations, bypass diodes electrically connected to the solar cells as described above, for example, are also located in the wiring channels. In other variations, such bypass diodes are located in other channels or cavities in substrate 130 and electrically connected by additional wires or conductors to the solar cells, or to conductors in the wiring channel, via additional holes in substrate 130.

In some other variations receiver 100 comprises electrically insulated interconnects (e.g., insulated wires or insulated conducting ribbons) that pass through holes in the substrate or wrap around one or more edges of the substrate to electrically connect solar cells on a front surface of the receiver to one or more junction/diode boxes (e.g., including bypass diodes and/or sockets as described above) on a rear surface of the receiver. Such electrically insulated interconnects may have a laminate structure, in some variations.

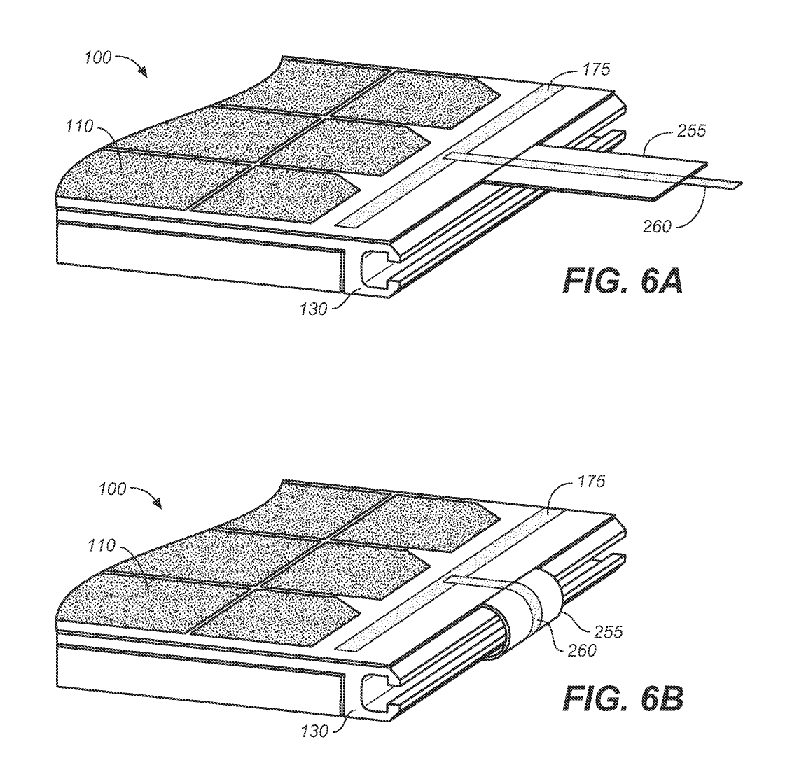

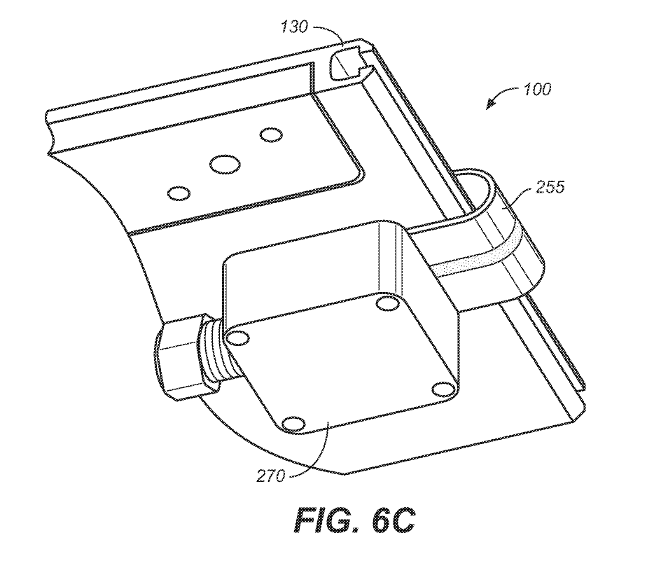

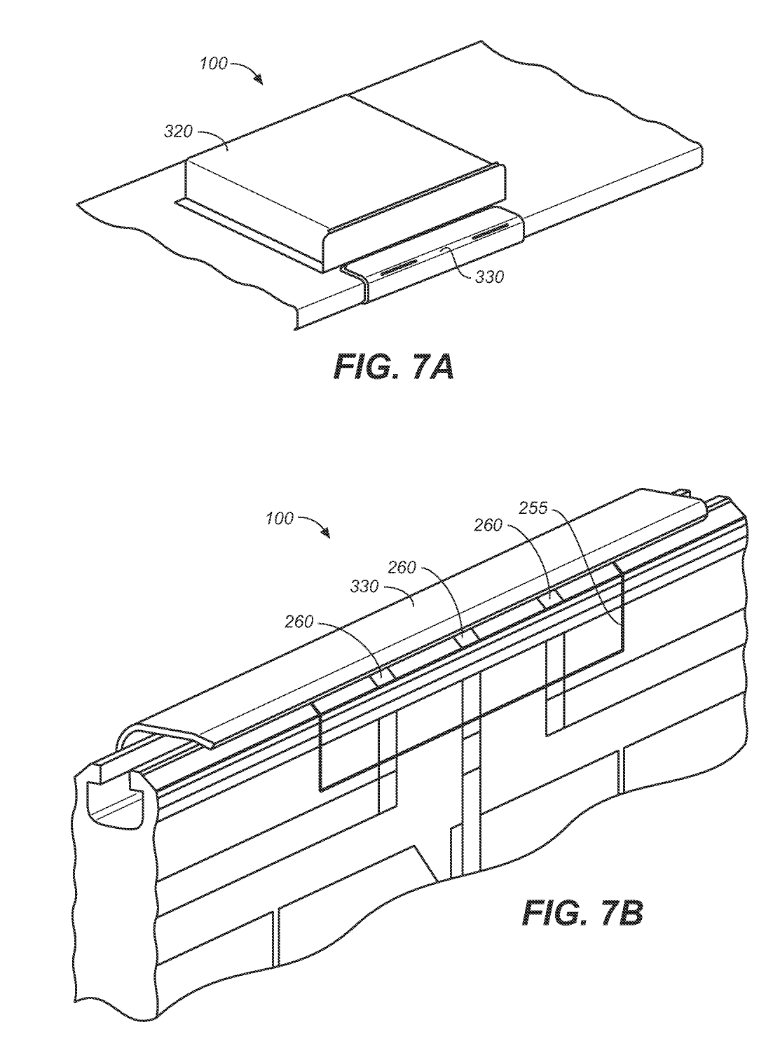

Referring now to FIG. 5B, for example, as well as to FIGS. 6A-6C, in some variations receiver 100 comprises one or more laminate structure interconnects 255 as electrically insulated interconnects electrically connecting solar cells 110 on a front (illuminated) surface of receiver 100 to one or more junction/diode boxes 270 on a rear (unilluminated) surface of receiver 100. In the illustrated example, interconnect 255 has a laminate structure comprising a first electrically insulating layer 280, an adhesive layer 290 disposed on insulating layer 280, an electrical interconnect 260 disposed on adhesive layer 280, a second adhesive layer 300 disposed on electrical interconnect 260, and a second insulating layer 310 disposed on adhesive layer 300. The adhesive layers hold the laminate structure together. Insulating layers 280 and 310 prevent inadvertent electrical contact between interconnect 260 and other portions of receiver 100.

Interconnect 260 extends beyond the other layers of laminate structure interconnect 255 to allow interconnect 260 to be electrically connected at one end to solar cells 110 (e.g., via bus bar 175) and electrically connected at another end to, e.g., a junction/diode box. In the illustrated example, one end portion of interconnect 260 extending beyond the other layers of laminate structure interconnect 255 is sandwiched, with solar cells 110 and their associated electrical interconnects, between adhesive layers 230 and 240 of laminate stack 120. An end portion of laminate structure interconnect 255 from which interconnect 260 protrudes may also be sandwiched between layers 230 and 240 of laminate stack 120 so that layers of laminate stack 120 and layers in laminate structure 255 overlap by, for example, about 5 mm, about 8 mm, about 12 mm, about 15 mm, about 20 mm, about 25 mm, or greater than about 25 mm. In some variations, the overlap is about 21 mm.

In some variations, each of insulating layers 280 and 310 has a thickness of about 50 μm to about 400 μm, or about 50 μm to about 125 μm, or about 100 μm to about 400 μm and is or includes an ETFE fluoropolymer such as, for example, Tefzel®, available from Dupont™; each of adhesive layers 290 and 300 has a thickness of about 200 μm to about 500 μm and is or includes any of the adhesive materials disclosed above for use in laminate stack 120; and interconnect 260 is formed from a copper ribbon conventionally tinned with solder.

In some variations in which laminate structure interconnect 255 includes ETFE (e.g., Tefzel) outer layers, these layers may be pre-treated with a conventional corona etching process on both sides of both layers (e.g., sheets), prior to assembly of laminate structure 255, to promote adhesion to layers in laminate structure 255 and to layers in stack 120.

In other variations, laminate structure interconnect 255 may include additional or fewer layers or may substitute different materials and/or thicknesses for one or more of the layers. Although in the illustrated example laminate structure interconnect 255 includes only a single electrical interconnect 260, in other variations laminate structure interconnect 255 may include two, three, four, or more interconnects 260. Laminate structure interconnect 255 may include as many interconnects 260 as necessary, for example, to electrically connect solar cells 110 to junction boxes and/or bypass diodes in configurations as described herein or as known to one of ordinary skill in the art.

In some variations, laminate structure interconnect 255 is formed prior to laminate stack 120, for example, by stacking the constituent layers of laminate structure interconnect 255 in the order described above and then heating them in a conventional laminator apparatus. In some such variations, lamination (i.e., formation) of interconnect 255 occurs at temperatures no greater than about 100° C. End portions of the resulting laminate, including an end portion of interconnect 260, may then be interleaved with layers from which laminate stack 120 is to be formed, and the resulting stack then laminated as described above with respect to stack 120. In other variations, the constituent layers of laminate structure interconnect 255 are stacked in the illustrated order and interleaved with the constituent layers of stack 120, also in the illustrated order, and then the resulting stack is laminated as above with respect to stack 120.

Referring now to FIGS. 6A-6C, laminate structure interconnect 255 may be bent to wrap around an edge of substrate 130 to allow laminate structure interconnect 255 to reach junction/diode box 270 and thus allow interconnect 260 to electrically connect solar cells 110 on the front side of receiver 100 with electrical components in junction/diode box 270 on the rear surface of receiver 100. Junction/diode box 270 may be mounted on the rear surface of receiver 100 with an adhesive or with screws or other mechanical connectors, for example, or by any other suitable means described herein or known to one of ordinary skill in the art. In some variations, laminate structure interconnect 255 is attached to substrate 130 with a silicone adhesive (e.g., PV804 available from Dow Corning®) and/or tape (e.g., VHB tape available from 3M™). Such attachment may be, for example, sufficient to prevent moisture from condensing on surfaces between interconnect 255 and substrate 130 and/or sufficient to provide a good heat conduction path between interconnect 255 and cooled substrate 130.

Receiver 100 is described in this specification as having an illuminated front side and an unilluminated rear or back side. It should be understood that these characterizations are meant to indicate that concentrated solar radiation may be intentionally directed to the (illuminated) front side, but not intentionally directed to the (unilluminated) back or rear side. Nevertheless, the back or rear side of receiver 100 may be illuminated by direct (not concentrated) solar radiation, and may be inadvertently illuminated by concentrated solar radiation. Laminate structure interconnect 255, described above, may also be exposed to direct solar radiation and/or inadvertently illuminated by concentrated solar radiation.

Referring now to FIGS. 1B, 7A, and 7B, in some variations one or more junction/diode boxes and/or electrical interconnects (e.g., interconnect 255 of FIGS. 6A-6C) are covered and thus shielded from illumination by direct or concentrated solar radiation by, respectively, junction/diode box shield 320 and/or interconnect shield 330.

Shields 320 and 330 may be formed, for example, from sheet metal, metal foil, adhesive metal foil, metal tape, or from a metalized plastic and may be attached to receiver 100 with, for example, any suitable adhesive (e.g., Dow Corning® PV804), tape (e.g., 3M™ VHB™ tape), or mechanical fastener. The metal in such metal sheets, foils, tapes, or metalized plastics may be or comprise, for example, aluminum (anodized, or not) or steel. Junction/diode box shield 320 may have the form of a box, for example. Interconnect shield 330 may have, for example, an approximately “L” shape, with the long portion on the rear surface of receiver 100 and the short portion wrapping around a side of receiver 100. Shields 320 and 330 may be configured to maintain a small gap of about 1.5 mm between the shield and the shielded component (e.g., junction/diode box or interconnect) to prevent a shield heated by (e.g., concentrated) solar radiation from damaging the shielded component. In other variations, a heat conducting adhesive (e.g., PV804) may be used to couple the shield, the shielded component, and cooled substrate 130 in order to prevent such damage.

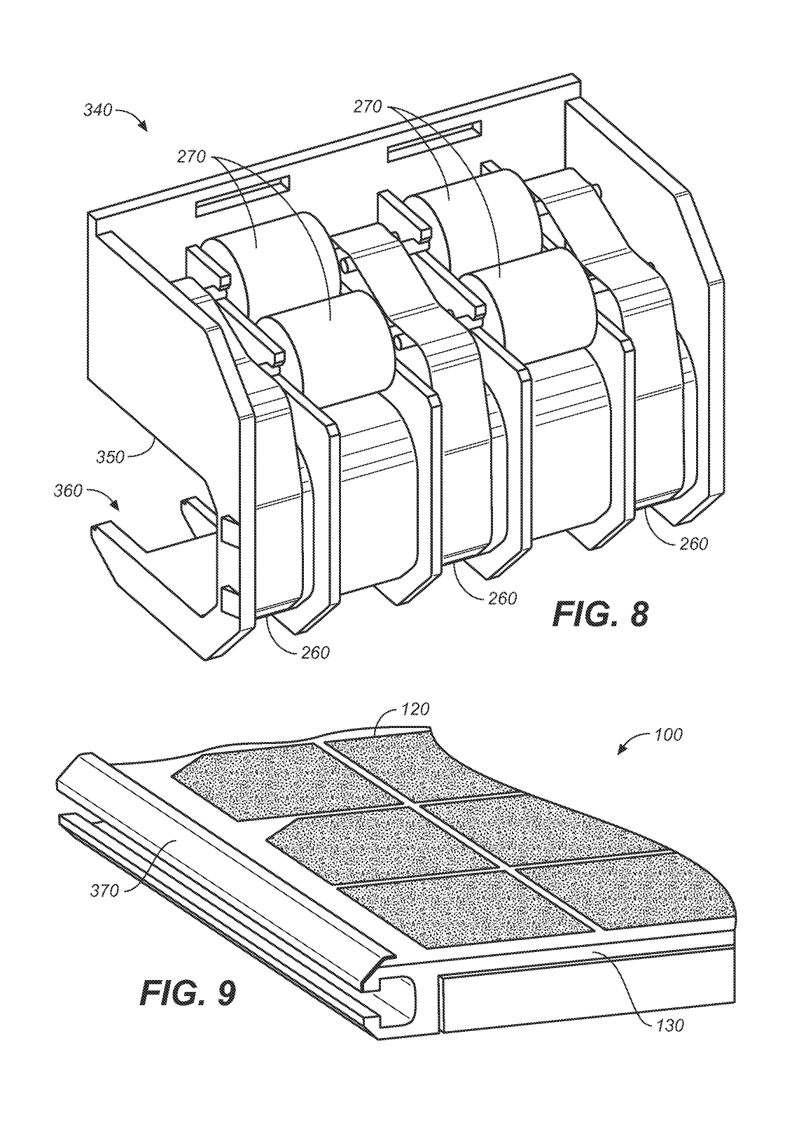

Referring now to FIG. 8, in another variation a junction/diode box 340 comprises a C-shaped portion 350 defining a slot 360 dimensioned to fit around (and optionally, clip on to) an edge of substrate 130 to locate bypass diodes 270 on a back (unilluminated) side of receiver 100. Interconnects 260 connect, e.g., diodes 270 in box 340 to bus bars and/or other electrical interconnects associated with solar cells 110. Such electrical connection to solar cells 110 may be accomplished, for example, through slits or openings in upper layers of laminations stack 120 (FIG. 5A, slits or openings not shown). Junction/diode box 340 may be formed, for example, from an engineering thermoplastic such as poly(p-phenylene oxide) (PPO) or similar material, from a metal, or from any other suitable material described herein or known to one of ordinary skill in the art. Junction/diode box 340 in FIG. 8 is shown with its lid or cover off. In use, a metal or plastic lid may be attached to box 340 to enclose the diodes and interconnects. In some variations, junction/diode box 340 may be shielded from solar radiation by an (e.g., sheet metal) outer box.

Referring now to FIG. 9, in some variations some or all edges of laminate structure 120 that would otherwise be exposed to the ambient environment are sealed. In the illustrated example, an edge of laminate structure 120 is sealed with a strip of tape 370 overlapping and adhering to laminate structure 120 and a side portion of substrate 130. Suitable tapes for this purpose may include, for example, 3M™ Aluminum Foil Tape 425. Tape 370 may overlap both the laminate structure and unlamented portions of substrate 130 by, for example, about 5 mm, about 10 mm, or more than about 10 mm.

As noted above with reference to FIG. 2A, substrate 130 of receiver 100 comprises coolant channels allowing coolant to be flowed through substrate 130 to collect heat from, and thus cool, solar cells 110. Any suitable arrangement of coolant channels, and any suitable coolant, may be used in receiver 100. In some variations, the coolant is or comprises water, ethylene glycol, or a mixture (e.g., equal parts by volume) of water and ethylene glycol.

The number and arrangement of the coolant channels may be selected, for example, to maintain temperature uniformity among solar cells 110 in directions transverse to the long axis of receiver 100, to minimize a change in temperature of solar cells 110 between opposite ends of receiver 100 along its long axis, to reduce a pressure drop for coolant flow between an inlet to and an outlet from the receiver, and/or to maintain support for front and back surfaces of substrate 130 (e.g., with ribs 137 shown in FIG. 2A) to reduce deformation of those surfaces under pressure occurring during operation (from coolant flow) or during lamination of substrate 130.

In some variations, substrate 130 comprises one, two, three, four, five, or more than five coolant channels running the length of substrate 130 parallel to its long axis. The channels may have, for example, approximately rectangular, approximately elliptical, or approximately circular cross sections, or any other suitably shaped cross section. Substrates comprising such combinations of number and shape of coolant channel may be formed, for example, from aluminum, aluminum alloys, or other suitable material by, for example, an extrusion process. In some variations, substrate 130 comprises three channels of approximately rectangular cross section having cross-sectional dimensions of about 55 mm by about 7.5 mm.

Flow of coolant through channels in substrate 130 may be controlled, in some variations, by orifices. In some variations, receiver 100 comprises a separate orifice ahead of (in the coolant flow path) and in series with each coolant channel. The orifices may be connected in parallel to a single coolant feed tube or conduit, for example. Such orifices may have, for example, a diameter (or largest dimension) of about 3 mm to about 8 mm. In some variations, the orifices have circular cross sections with diameters of about 4.7 mm. The ratio of the hydraulic diameter (4·cross-sectional area/cross-sectional perimeter) of a coolant channel to that of an orifice ahead of and in series with the channel in the coolant flow path may be, for example, about 2 to about 3, or greater than about 3. In some variations, the ratio is about 2.8. A pressure drop across each orifice during operation may be, for example, about 2 times greater than, or more than about 2 times greater than, a pressure drop across its corresponding coolant channel. In some variations, a pressure drop across each orifice during operation may be, for example, about five times greater than a pressure drop across its corresponding coolant channel.

The orifices may be provided, for example, as orifices all in a single gasket in a seal at a coolant input end of substrate 130, as orifices in two or more gaskets (e.g., a separate gasket for each orifice) in one or more seals at a coolant input end of substrate 130, as orifices in one or more plugs at a coolant input end of substrate 130, or in any other suitable manner described herein or known to one of ordinary skill in the art.

Coolant may be delivered to the coolant channels, through orifices where used, by separate coolant feed tubes or conduits for each channel. Alternatively, coolant may be delivered by one or more coolant feed tubes or conduits to one or more coolant manifolds which distribute the coolant to the individual coolant channels.

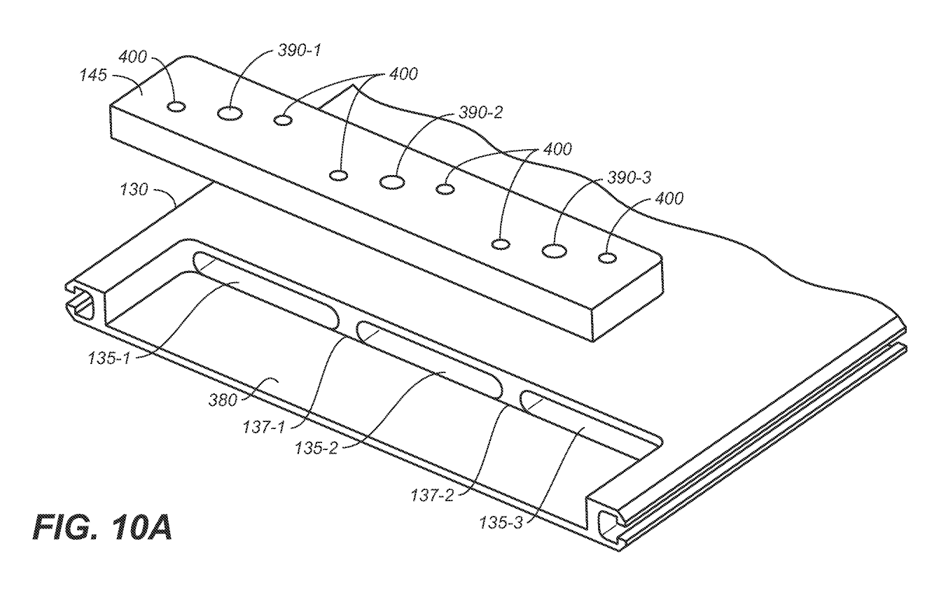

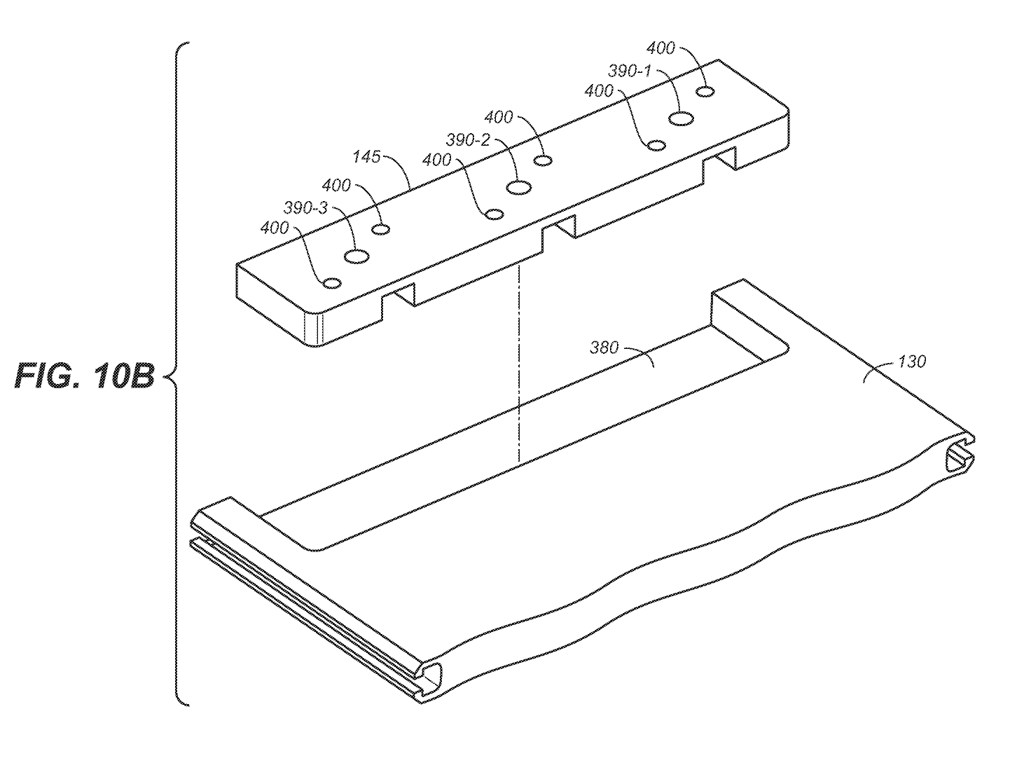

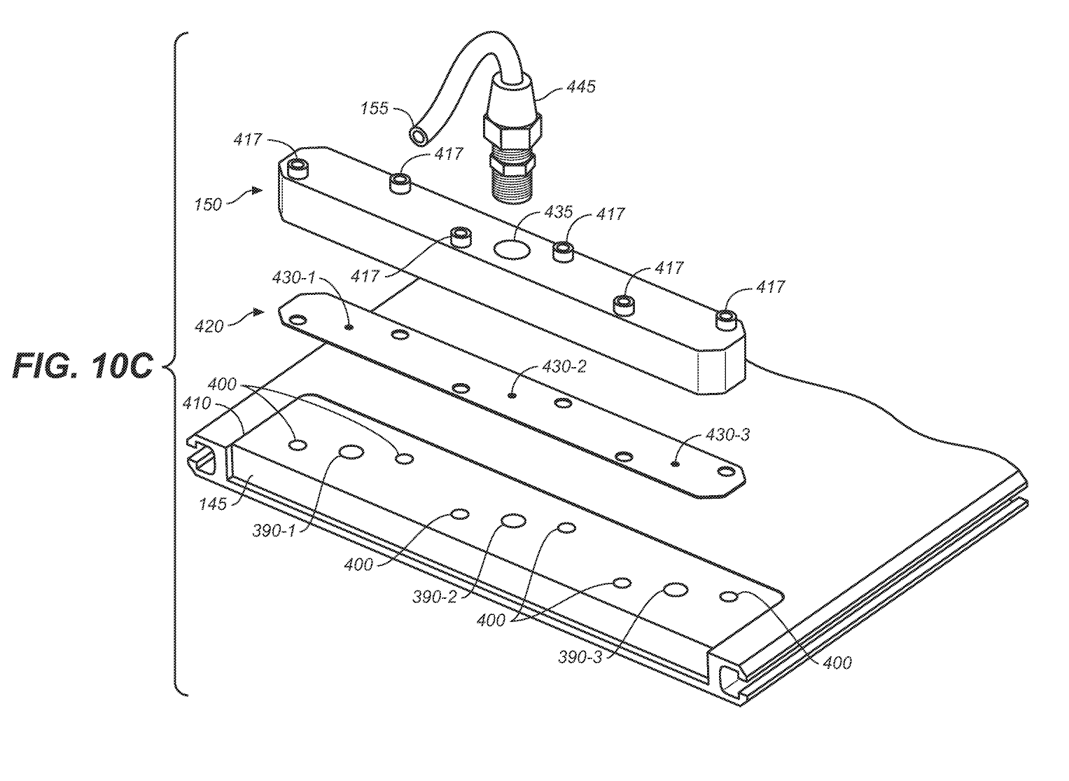

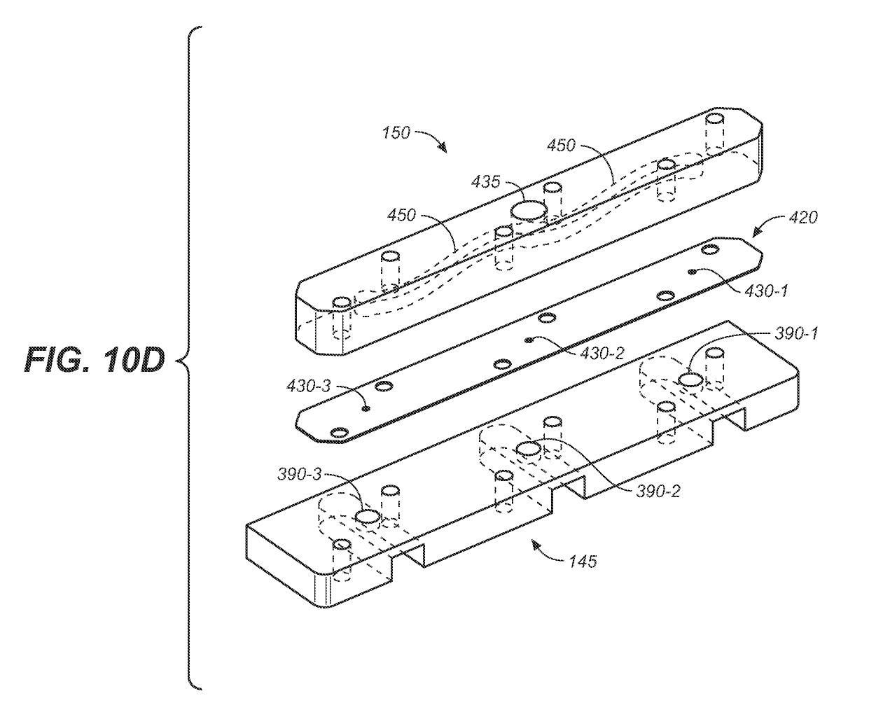

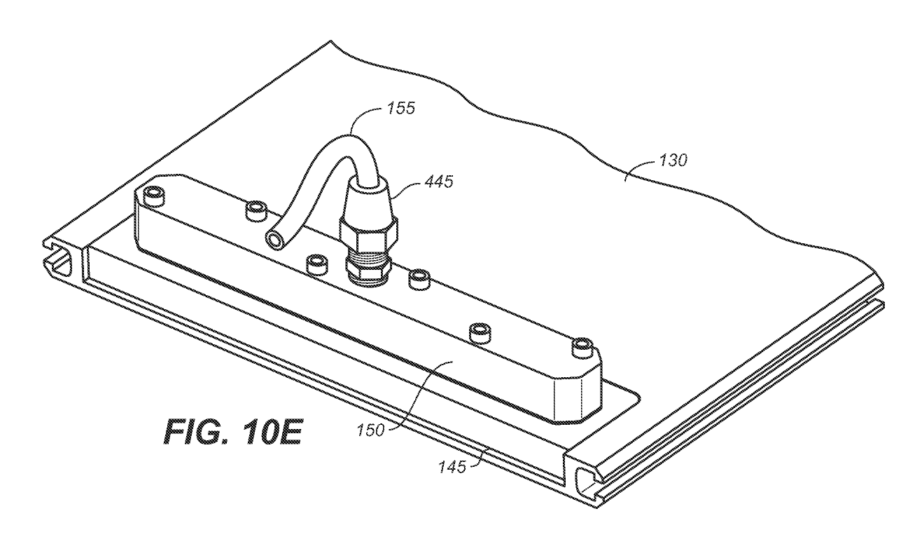

Referring now to FIGS. 10A and 10B (as well as to FIGS. 1B and 2B), in one variation an end cap 145 fits into a (e.g., three sided) slot 380 in substrate 130 to provide fluid paths 390-1, 390-2, and 390-3 to, respectively, coolant channels 135-1, 135-2, and 135-3 and to otherwise seal the end of substrate 130. End cap 145 may be machined or cast, for example, and may be formed from aluminum, aluminum alloys, copper, steel, stainless steel, fiberglass, ceramics, or any other suitable material. End cap 145 may be attached to substrate 130 by, for example, compression fitting, welding (e.g., aluminum welding), brazing, dip brazing, soldering, gluing, or any suitable method described herein or known to one of ordinary skill in the art. End cap 145 may further comprise optional threaded holes 400 by which a fluid manifold (discussed below) may be mounted to end cap 145. Any suitable number and size of such threaded holes (and corresponding bolts, screws, or other threaded fasteners) may be used.

Referring now to FIGS. 10C and 10D (as well as to FIG. 1B), in one example a seal 410 to substrate 130 is formed between end cap 145 and substrate 130 by any of the attachment methods (e.g., compression fitting, aluminum welding, dip brazing, soldering) described above. In the illustrated example, a fluid manifold 150 is mounted to end cap 145 with threaded fasteners 417 engaging threaded holes 400. A gasket 420 between manifold 150 and end cap 145 seals their interface. Gasket 420 comprises orifices 430-1, 430-2, and 430-3 controlling the flow of coolant from manifold 150 through, respectively, fluid paths 390-1, 390-2, and 390-3 and thus into and through, respectively, coolant channels 135-1, 135-2, and 135-3. Manifold 150 comprises a threaded hole 435 by which a coolant interconnect (e.g., feed) tube 155 may be connected to manifold 150 with e.g., compression fittings 445, and channels 450 which deliver fluid to orifices 430-1 and 430-3. FIG. 10E shows substrate 130, end cap 145, manifold 150, fluid interconnect 155, and fittings 445 in an assembled configuration, according to some variations.

Manifold 150 may be machined or cast, for example, and may be formed, for example, from aluminum, aluminum alloys, PPO, fluoropolymers (e.g., Teflon®), silicone, zinc, or any other suitable material. Though manifold 150 in the illustrated example is attached to end cap 145 with threaded fasteners, any other suitable method of attachment described herein or known to one of ordinary skill in the art may be used. Manifold 150 may be attached to end cap 145 by welding, brazing, or gluing, for example. Gasket 420 may be formed, for example, from a silicone or a fluoropolymer elastomer (e.g., Viton®) by a die-cutting process, for example. Feed tube 155 may be, for example, a 0.25 inch diameter tube, a 0.375 inch diameter tube, or any other suitable diameter tube and may be formed from aluminum, copper, plastic (e.g., cross-linked polyethylene (PEX)), or any other suitable material. Plastic tubing used for feed tube 155 may be optionally wrapped in silicone or aluminum foil. Fittings 445 may be, for example, conventional pipe fittings of suitable size for the tube.

Although the example of FIGS. 10C and 10D utilizes three orifices controlling coolant flow through, respectively, three fluid paths in end cap 145 and then through, respectively, three coolant channels in substrate 130, other numbers and combinations of orifices, fluid flow paths, and coolant channels may be used. Some variations may utilize two orifices controlling coolant flow through, respectively, two fluid paths in end cap 145 and then through, respectively, two coolant channels in substrate 130. Some other variations may utilize four orifices controlling coolant flow through, respectively, four fluid paths in end cap 145 and then through, respectively, four coolant channels in substrate 130.

Although the discussion above has been with respect to the flow of coolant into and through receiver 100, the same or similar types of assemblies (e.g., comprising an end cap, a fluid manifold, and a fluid interconnect) may be used as a coolant outlet from receiver 100. The outlet coolant flow path need not include any flow controlling orifice or orifices inducing a large pressure drop, however. In some variations, coolant is output from receiver 100 through an assembly essentially identical to an assembly through which coolant is input to receiver 100, apart from the absence of any flow control orifice in the outlet inducing a large pressure drop.

In some variations, the entire coolant fluid flow path through receiver 100 is formed from a same material such as, for example, aluminum or an aluminum alloy.

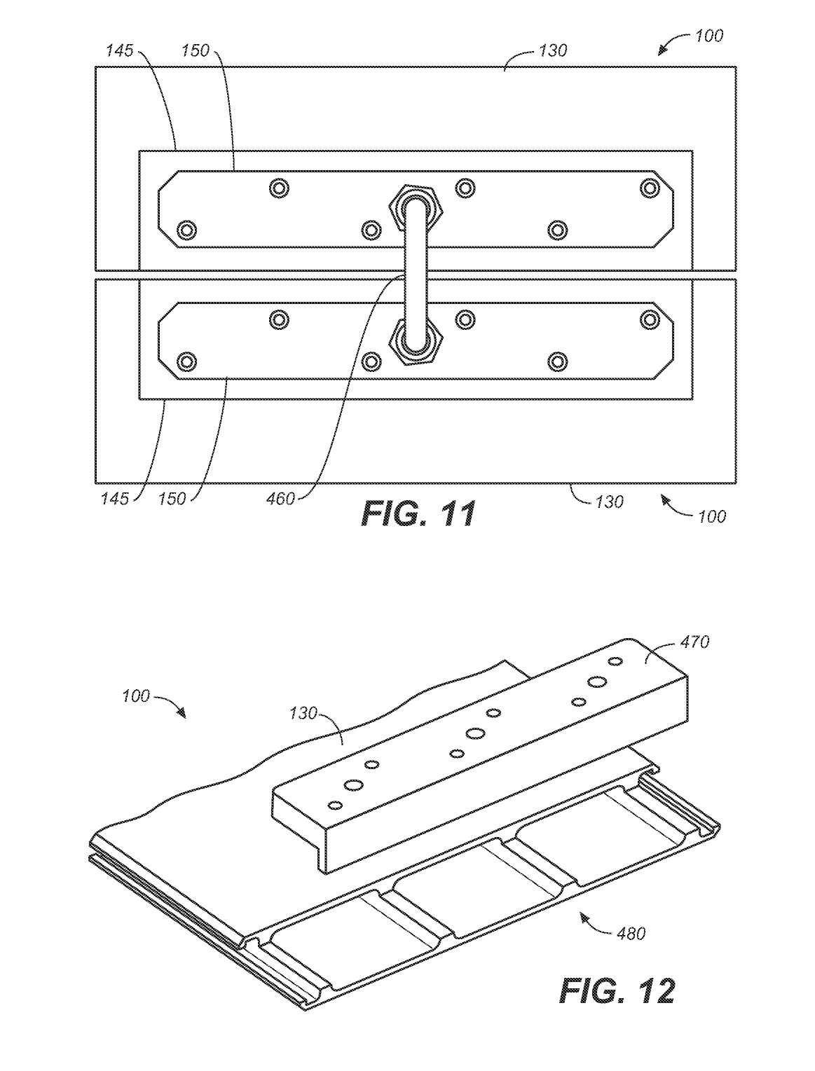

As noted above, two or more receivers 100 may be positioned, e.g., end-to-end and interconnected to form a larger receiver. Referring now to FIG. 11, in some variations two receivers 100 are positioned end-to-end with a fluid interconnection tube 460 interconnecting coolant channels in the receivers. Fluid interconnection may be via end fluid manifolds 150 and end caps 145, as illustrated in FIG. 11, or by any other suitable manner of delivering coolant to coolant channels in the substrates 130 described herein or known to one of ordinary skill in the art. Fluid interconnect tube 460 may be formed from any of the materials disclosed above for fluid interconnection tubes 155, for example. In some variations, fluid interconnection tube 460 between receivers 100 provides strain relief. Such strain relief may accommodate, for example, thermal expansion of receivers 100 during operation.

FIG. 12 shows another example providing for flow of coolant fluid into and through coolant channels in substrate 130. In this example, an end cap 470 having an L-shaped cross section fits onto and over a portion 480 of substrate 130 from which the rear surface is absent (e.g., removed by saw cut). End cap 470 may be attached to substrate 130 by any of the methods described above (e.g., aluminum weld). A fluid manifold and fluid interconnect similar or identical to any of those described above may be mounted on end cap 470 by any of the methods described above.

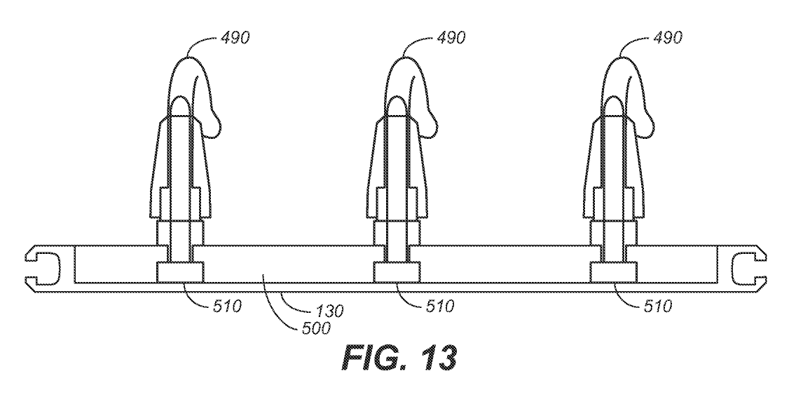

Some variations do not utilize a fluid manifold to distribute coolant from an inlet to multiple coolant channels in substrate 130, but instead use multiple inlets each delivering coolant directly to corresponding individual channels in substrate 130. Referring to FIG. 13, for example, in some variations two, three, or more fluid interconnect tubes 490 are coupled to an end cap 500 (attached to substrate 130) by fittings 510. Each interconnect tube 490 is in fluid communication with a different one of a plurality of coolant channels in substrate 130 through a separate flow path in end cap 500. In some variations, coolant flow through one or more of the coolant channels is controlled by one or more orifices located in the corresponding flow paths through end cap 500. In other variations, flow control orifices are not used. In some variations, a receiver having separate fluid interconnects for each coolant channel in substrate 130 as just described, and including a flow control orifice for each coolant channel in substrate 130, is fluidly coupled in series with one or more otherwise similar receivers that do not utilize any flow control orifices.

Other methods for sealing or plugging ends of coolant channels in substrate 130 may also be used. Ends of coolant channels may be sealed, for example, with tapered plugs formed from compliant materials (e.g., plastics or epoxies) into shapes that conform with and may be introduced (e.g., wedged) into the ends of the channels to form a seal, or with plugs that may introduced into the channels to form gasket or o-ring seals. In variations in which the ends of coolant channels in substrate 130 are sealed with plugs that do not provide for introducing coolant into the channels through the plugs, coolant may be introduced into the coolant channels, for example, through interconnects fluidly coupled to the coolant channels through (e.g., tube fittings in or a fluid manifold on) the rear (unilluminated) surface of the substrate. Such interconnects, tube fittings, and fluid manifolds may be similar to, and be positioned similarly to, those described above.

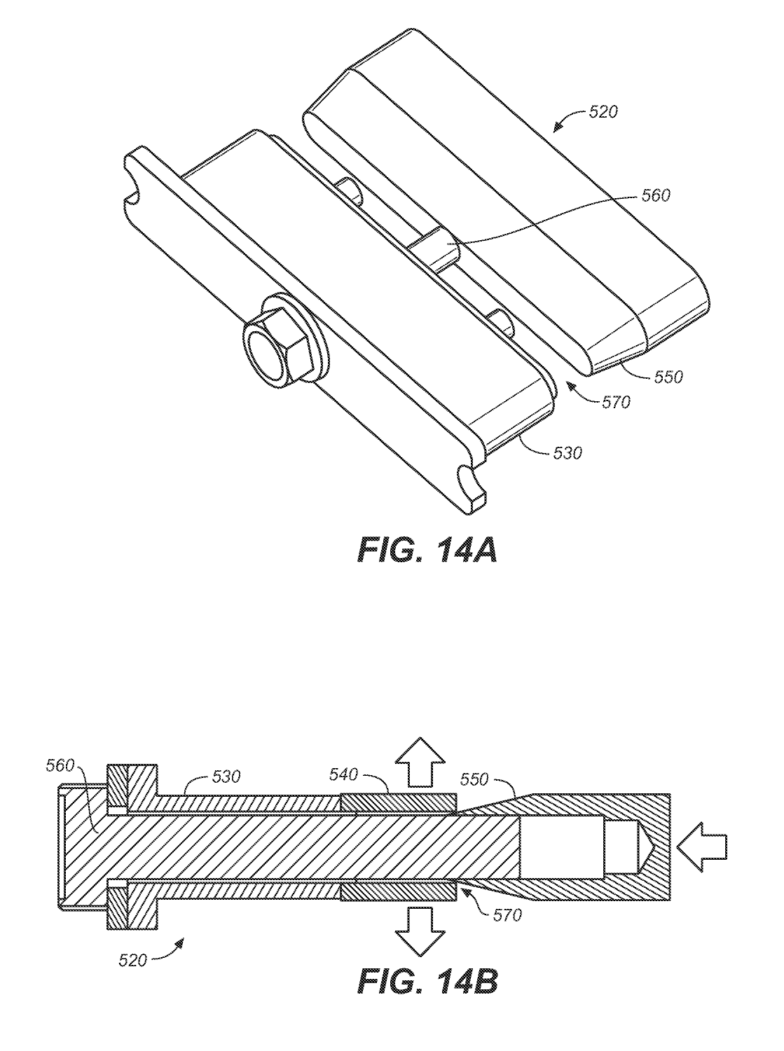

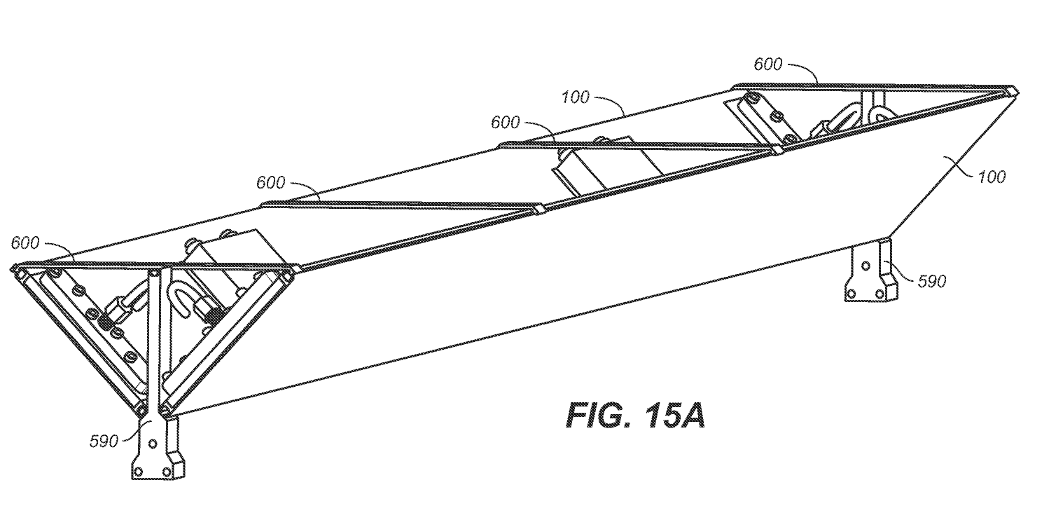

Referring now to FIGS. 14A and 14B, in some variations a compression plug 520 may be inserted into and used to seal an end of a coolant channel in substrate 130. Compression plug 520 comprises a plug portion 530, an optional gasket 540 (not shown in FIG. 14A), a wedge portion 550, and a threaded rod (e.g., screw) 560 by which the wedge portion 550 may be drawn into an interior end portion 570 of plug portion 530 and/or gasket 540 to force interior end portion 570 and/or gasket 540 outward and into contact with walls of a coolant channel (not shown) to seal the coolant channel. To form such a seal, the compression plug is inserted into the end of a coolant channel in uncompressed form, and then wedge portion 550 is drawn toward plug portion 530 until a sufficient seal has been achieved.

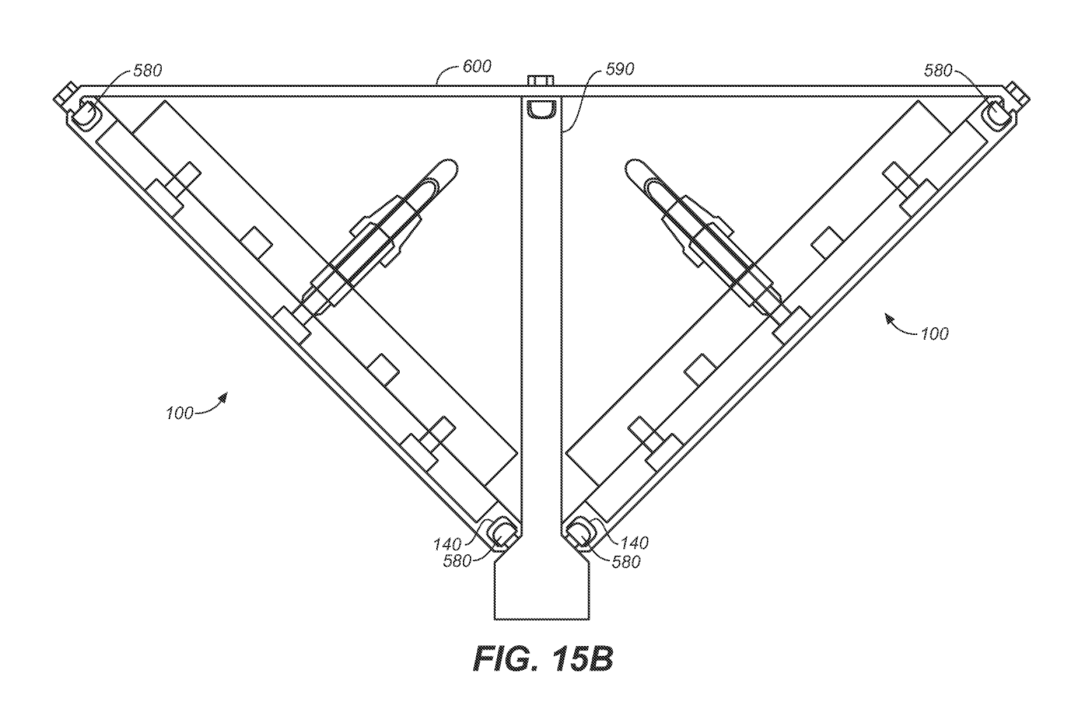

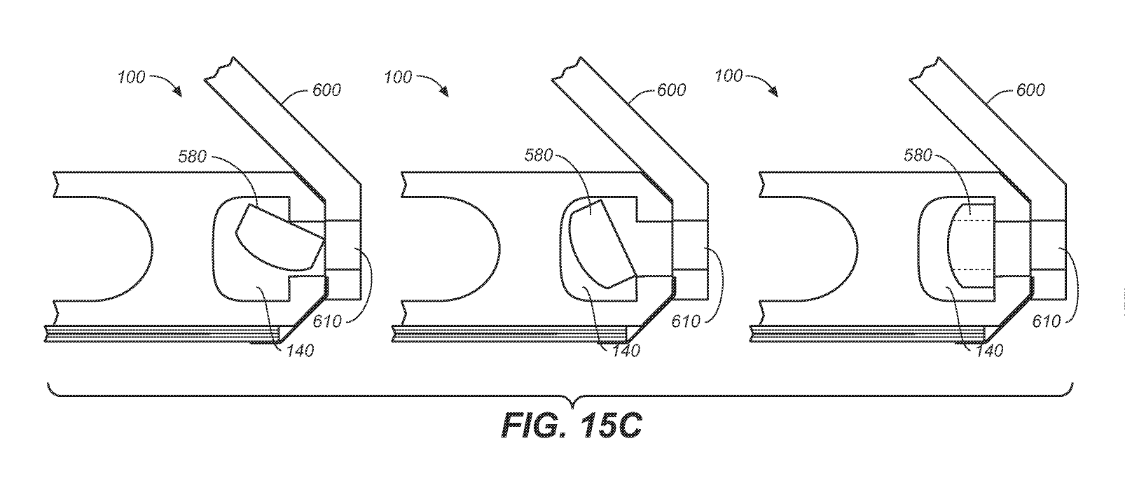

In some variations two receivers 100 may be arranged and mechanically connected to form a V shape. Such a V-shape arrangement may provide additional stiffness, and may also position receivers 100 to be more effectively illuminated by concentrated solar radiation. In the example of FIGS. 15A-15C, two receivers 100 are oriented with their long axes parallel to each other and with each receiver rotated around its long axis by about 45° from the horizontal such that the two receivers form an approximately V shape (with an intersecting angle between them of about 90°) with their solar cells facing downward. T-slots 140 on lower edges of receivers 100 engage fasteners (e.g., a nut and/or bolt) 580 on a vertical support 590 to attach the receivers to the vertical support. T-slots 140 on upper edges of receivers 100 engage fasteners (e.g. a nut and or bolt) 580 located at ends of transverse brackets 600 to attach the receivers to the brackets and thereby to each other.

The solar cells disposed on the first substrate may be electrically connected, for example, in series or in parallel with those on the second substrate. Coolant may flow, for example, in series or in parallel through the first and second substrates. Hence, coolant may be input to and output from the V-shaped assembly of receivers at the same end (series flow) or at opposite ends (parallel flow).

Although FIG. 15A shows a bracket 600 located at each end of receivers 100 and two brackets at intermediate locations between the ends of the receivers, more or fewer brackets may be used and brackets may be placed in any suitable location. In some variations, brackets are placed at intervals of about 0.5 to about 1.5 meters (e.g., about 0.6 meters, about 0.7 meters, or about 0.8 meters) along receivers 100.

FIG. 15C shows a sequence of three diagrams depicting the introduction of a nut 580 into a t-slot 140 in a receiver 100, and its rotation inside t-slot 140 into alignment with an opening of t-slot 140 and a through-hole 610 in a bracket 600. A bolt or other threaded fastener (not shown) may then engage nut 580 through hole 610 to attach bracket 610 to receiver 100.

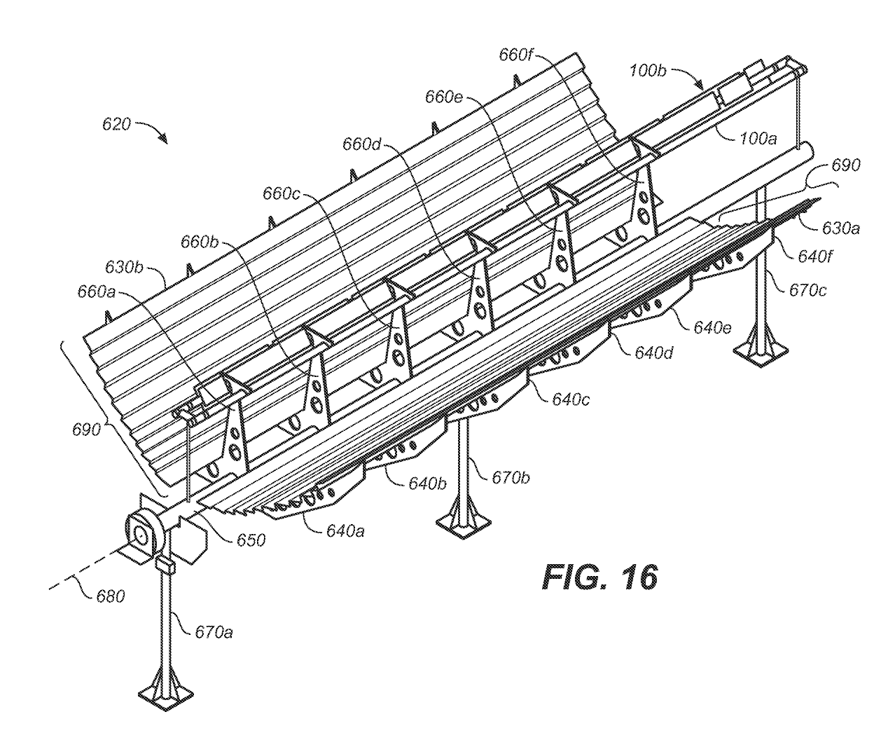

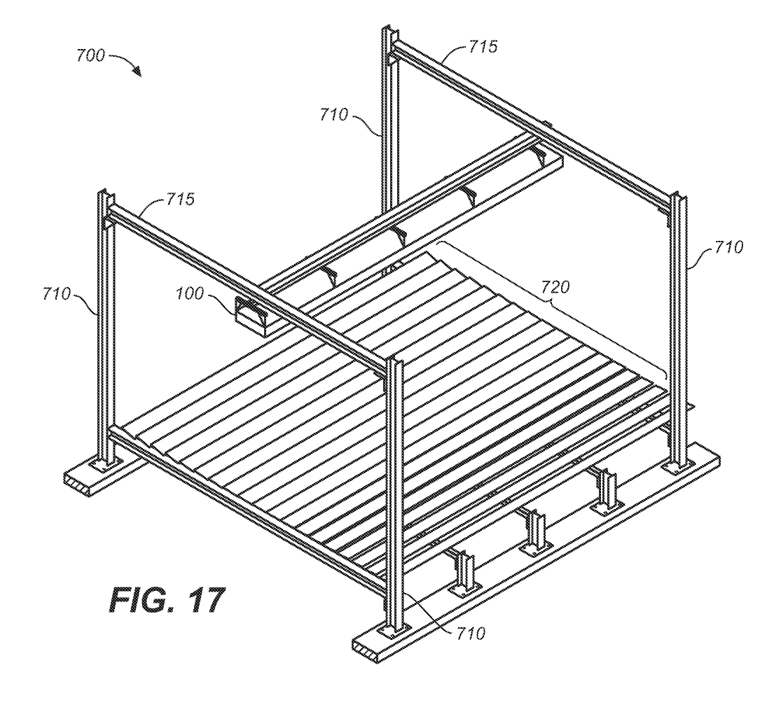

Referring now to FIG. 16, in some variations receivers as disclosed herein may be used in trough solar energy collection systems such as, for example trough solar energy collector 620. Trough solar energy collector 620 comprises linearly extending reflectors 630a and 630b supported by transverse ribs 640a-640f and attached thereby to longitudinally extending torque tube 650. Linearly extending receivers 100a and 100b, arranged in a V-shape as described above, for example, are attached to and positioned above torque tube 650 by vertical supports 660a-660f to locate receiver 100a at approximately a linear focus of reflector 630a and to locate receiver 100b at approximately a linear focus of reflector 630b.

Torque tube 650 is pivotably attached to support posts 670a-670c, allowing reflectors 630a and 630b to rotate together with receivers 100a and 100b around pivot axis 680 to orient reflectors 630a and 630b to reflect solar radiation from the sun to, respectively, receivers 100a and 100b.

Reflectors 630a and 630b each comprise a plurality of linearly extending flat mirrors 690 supported by ribs 640a-640f to approximate a parabolic curvature. The aspect ratio (length divided by width) of flat mirrors 690 in the surface of reflectors 630a, 630b may be, for example, about 10:1, about 20:1, about 30:1, about 40:1, about 50:1, about 60:1, about 70:1, about 80:1, about 90:1, about 100:1, about 110:1, about 120:1, or more than about 120:1. In one example, mirrors 690 are about 11.1 meters long and about 0.10 meters wide (aspect ratio about 112:1). In another example, mirrors 690 are about 11.1 meters long and about 0.13 meters wide (aspect ratio about 86:1). In some variations, mirrors 690 may be assembled from shorter length mirrors, having lengths as short as about 1 meter, positioned end to end.

Although FIG. 16 shows trough solar energy collector 620 comprising particular numbers of receiver supports, ribs, posts, and flat mirrors, these components may be present in greater or lesser numbers than as shown. Also, although trough solar energy collector 620 in the illustrated example comprises two receivers 100 oriented to form a V shape, other variations may comprise instead one or more horizontally oriented receivers 100 running parallel to rotation axis 680.

Referring now to FIG. 17, in some variations receivers as disclosed herein may be used in linear Fresnel solar energy collection systems such as, for example linear Fresnel solar energy collector 700. Linear Fresnel solar energy collector 700 comprises a receiver 100 elevated by vertical supports 710 and cross beams 715 above reflector rows 720 arranged parallel to and beneath receiver 100. Each of the individual reflector rows is configured to rotate about its own pivot axes, which is parallel to its long axis and hence parallel to receiver 100. By such rotation the reflector rows may be oriented to reflect solar radiation from the sun to a linear focus along receiver 100. The reflectors may be flat or have, for example, parabolic or approximately parabolic curvature with focal lengths of approximately the distance from the reflector center lines to the center line of the lower surface of receiver 100. Although in the illustrated example solar energy collector 700 is shown as comprising a horizontally oriented receiver 100, some other variations may comprise instead two receivers oriented to form a V-shape as described above.

One of ordinary skill in the art will recognize that linear Fresnel collectors are known in the art, and that features of the support structures and the general arrangement of the reflectors with respect to the receiver are intended as schematic illustrations representing numerous configurations known in the art.

This disclosure is illustrative and not limiting. Further modifications will be apparent to one skilled in the art in light of this disclosure and are intended to fall within the scope of the appended claims. All publications and patent applications cited in the specification are incorporated herein by reference in their entirety as if each individual publication or patent application were specifically and individually put forth herein.

1-34. (canceled)

35. A solar energy receiver comprising:
a substrate having a front surface, a back surface opposite to the front surface, and side surfaces;
a plurality of solar cells disposed in a stack of laminated layers on the front surface of the substrate;
one or more electrical components disposed on the back surface of the substrate; and
an electrically insulated interconnect comprising a laminated structure including one or more electrical conductors laminated between two or more electrically insulating layers, the electrically insulated interconnect wrapping around a side surface of the substrate to electrically interconnect one or more of the solar cells on the front surface of the substrate to one or more of the electrical components on the back surface of the substrate.

36. The solar energy receiver of claim 35, wherein at least an end portion of the laminated structure of the electrically insulated interconnect overlaps with and is included in the stack of laminated layers on the front surface of the substrate.

37. The solar energy receiver of claim 35, comprising a solar radiation shield positioned to protect the laminated structure of the electrically insulated interconnect from illumination by solar radiation.

38. The solar energy receiver of claim 35, wherein the substrate is linearly extending along a long axis and comprises two or more coolant channels extending through the substrate along its long axis.

39. The solar energy receiver of claim 38, comprising a compression plug at least partially inserted into and sealing an end of one of the coolant channels, wherein the compression plug comprises a gasket on a plug portion and a wedge portion that may be drawn against the plug portion to press the gasket against an interior wall of a coolant channel to thereby seal the coolant channel.

40. The solar energy receiver of claim 38, where the substrate is formed by an extrusion process.

41. The solar energy receiver of claim 35, wherein the substrate is linearly elongated and comprises two or more coolant channels extending through the substrate along its long axis, and at least an end portion of the laminated structure of the electrically insulated interconnect overlaps with and is included in the stack of laminated layers on the front surface of the substrate, comprising a solar radiation shield positioned to protect the laminated structure of the electrically insulated interconnect from illumination by solar radiation.

42. A solar energy collector comprising the solar energy receiver of claim 41 and one or more reflectors arranged to concentrate solar radiation onto the solar cells.

43. The solar energy collector of claim 42, wherein the solar radiation shield protects the laminate structure of the electrically insulated interconnect from solar radiation concentrated by the one or more reflectors.

44. A solar energy receiver comprising:
a linearly extending substrate comprising two or more coolant channels extending through the substrate along its long axis; and
solar cells in thermal contact with the substrate;
wherein the substrate is formed by an extrusion process.

45. The solar energy receiver of claim 44 wherein the coolant channels have substantially rectangular cross sections perpendicular to the long axis of the substrate.

46. The solar energy receiver of claim 44 wherein the solar cells are included in a stack of two or more laminated layers disposed on the substrate.

47. The solar energy receiver of claim 44, wherein the coolant channels have substantially rectangular cross sections perpendicular to the long axis of the substrate, the solar cells are included in a stack of two or more laminated layers disposed on the substrate, and the substrate is formed from aluminum or an aluminum alloy by an extrusion process.

48. The solar energy receiver of claim 47, comprising an electrically insulated interconnect that comprises a laminated structure including one or more electrical conductors laminated between two or more electrically insulating layers, the electrically insulated interconnect wrapping around a side surface of the substrate to electrically interconnect one or more of the solar cells on a front surface of the substrate to one or more electrical components on a back surface of the substrate.

49. A solar energy collector comprising the receiver of claim 48 and one or more reflectors arranged to concentrate solar radiation onto the solar cells.

50. A solar energy receiver comprising:
a linearly extending substrate comprising two or more coolant channels extending through the substrate along its long axis;
solar cells in thermal contact with the substrate; and
a compression plug at least partially inserted into and sealing an end of one of the coolant channels.

51. The solar energy receiver of claim 50, wherein the compression plug comprises a gasket on a plug portion and a wedge portion that may be drawn against the plug portion to press the gasket against an interior wall of a coolant channel to thereby seal the coolant channel.

52. The solar energy receiver of claim 16, wherein the solar cells are disposed on a front surface of the substrate, comprising a coolant manifold located on a back surface of the substrate and fluidly coupled to the coolant channels.

53. The solar energy receiver of claim 50, wherein the compression plug comprises a gasket on a plug portion and a wedge portion that may be drawn against the plug portion to press the gasket against an interior wall of a coolant channel to thereby seal the coolant channel, and wherein the solar cells are disposed on a front surface of the substrate, comprising a coolant manifold located on a back surface of the substrate and fluidly coupled to the coolant channels.

54. A solar energy collector comprising the solar energy receiver of claim 53 and one or more reflectors arranged to concentrate solar radiation onto the solar cells.
